(19) United States
(12) Patent Application Publication
(10) Pub. No.: US 2025/0102588 A1
(43) Pub. Date: Mar. 27, 2025

(54) MONITORING BATTERY TEMPERATURE USING ELECTROCHEMICAL IMPEDANCE SPECTROSCOPY

(71) Applicant: Analog Devices International Unlimited Company, Limerick (IE)

(72) Inventors: Gina Aquilano, Somerville, MA (US); Shane O'Mahony, Grenagh (IE); Joseph Caissie Bush, Franklin, MA (US)

(21) Appl. No.: 18/629,704

(22) Filed: Apr. 8, 2024

Related U.S. Application Data
(60) Provisional application No. 63/585,061, filed on Sep. 25, 2023.

(51) Int. Cl. G01R 31/389; G01R 31/367; G01R 31/3835; G01R 31/392; G01R 31/396

(52) U.S. Cl. CPC G01R 31/389; G01R 31/367; G01R 31/3835; G01R 31/392; G01R 31/396

(57) ABSTRACT

An electrochemical impedance spectroscopy (EIS) monitoring system for determining a parameter value corresponding to a cell arrangement including two or more electrochemical cells can include an EIS measurement system, which can be configured to determine a representation of respective temperature values corresponding to at least two of the two or more electrochemical cells using an EIS measurement of corresponding ones of the at least two electrochemical cells. The EIS monitoring system can also include an assessment circuit, which can be configured to compare the representations of respective temperature values to representations of respective reference temperature values. The assessment circuit can also be configured to determine a parameter value corresponding to at least one of the cell arrangement or one or more of the respective ones of the at least two electrochemical cells using a result of the comparison.

### CLAIM OF PRIORITY

This patent application claims the benefit of priority of Aquilano et al., U.S. Provisional Patent Application Ser. 63/585,061, entitled “USING BATTERY CORE TEMP FOR FAULT DETECTION,” filed on Sep. 25, 2023 (Attorney Docket No. 3867.B78PRV), which is hereby incorporated by reference herein in its entirety.

### TECHNICAL FIELD

The present disclosure relates to battery monitoring systems, and more particularly, but not by way of limitation, to an electrochemical impedance spectroscopy battery monitoring system.

### BACKGROUND

Modern systems, such as energy storage systems and electrolysis systems, can use electrochemical cells. Energy storage systems can include batteries or fuel cells, and can be a main power source or an auxiliary power source. Electrolysis systems can include electrolysis cells, such as for driving a chemical reaction using electrical energy. Examples of such modern systems can include consumer electronics, industrial electronics, passenger cars, industrial trucks, and industrial processing plants. Monitoring a parameter of a cell, such as the state of charge (SoC) or the state of health (SoH), can help ensure reliable operation of the system and avoid unnecessary damage to the cell, such as due to overheating.

### SUMMARY

In an example, an electrochemical impedance spectroscopy (EIS) monitoring system for determining a parameter value corresponding to a cell arrangement including two or more electrochemical cells can include an EIS measurement system, which can be configured to determine a representation of respective temperature values corresponding to at least two of the two or more electrochemical cells using an EIS measurement of corresponding ones of the at least two electrochemical cells. The EIS monitoring system can also include an assessment circuit, which can be configured to compare the representations of respective temperature values to representations of respective reference temperature values, where the representations of respective reference temperature values can be determined based on expected temperature values of a reference cell arrangement configured similarly to the cell arrangement and under similar conditions as the cell arrangement. The assessment circuit can also be configured to determine a parameter value corresponding to at least one of the cell arrangement or one or more of the respective ones of the at least two electrochemical cells using a result of the comparison.

In an example, a method for determining a parameter value corresponding to a cell arrangement including two or more electrochemical cells can include making an EIS measurement of respective individual ones of at least two of the two or more electrochemical cells. The method can also include determining a representation of respective temperature values corresponding to the at least two of the two or more electrochemical cells using the respective EIS measurements. The method can also include determining representations of respective reference temperature values based on expected temperature values of a reference cell arrangement configured similarly to the cell arrangement and under similar conditions as the cell arrangement. The method can also include comparing the representations of respective temperature values to representations of respective reference temperature values. The method can also include determining a parameter value corresponding to at least one of the cell arrangement or one or more of the respective ones of the at least two electrochemical cells using a result of the comparison.

In an example, an electrochemical impedance spectroscopy (EIS) monitoring system for determining a parameter value corresponding to a cell arrangement including two or more electrochemical cells can include an EIS measurement system, which can be configured to determine respective change in temperature values corresponding to at least two of the two or more electrochemical cells using an EIS measurement of corresponding ones of the at least two electrochemical cells, where the change in temperature values can be due to charging of the cell arrangement at a specified rate for a specified length of time. The EIS monitoring system can also include an assessment circuit, which can be configured to trend the change in temperature values of respective individual ones of the electrochemical cells across at least two charging events, and compare the trend to a reference trend based on an expected degradation of an electrochemical cell.

### BRIEF DESCRIPTION OF THE DRAWINGS

In the drawings, which may not be drawn to scale, like numerals may describe substantially similar components throughout one or more of the views. Like numerals having different letter suffixes may represent different instances of substantially similar components. The drawings illustrate generally, by way of example but not by way of limitation.

FIG. 1 is a schematic drawing of portions of an electrochemical impedance spectroscopy (EIS) monitoring system.

FIG. 2A is a schematic drawing of an example of portions of a cell arrangement.

FIG. 2B is a schematic drawing of an example of portions of a cell arrangement.

FIG. 2C is a schematic drawing of an example of portions of a cell arrangement.

FIG. 3 shows an example of portions of a method for operating an EIS monitoring system.

FIG. 4 shows an example of portions of a method for operating a EIS monitoring system.

FIG. 5 is a block diagram illustrating an example of a machine upon which one or more examples may be implemented.

### DETAILED DESCRIPTION

One approach to estimate or measure a parameter of an electrochemical cell, such as the SoC or SoH, is electrochemical impedance spectroscopy (EIS). EIS can include measuring the impedance (e.g., DC resistance, AC impedance, complex impedance (e.g., the AC impedance including a real and imaginary component based upon the phase relationship of voltage and current)) of a cell arrangement of electrochemical cells at one or more frequencies. The determined complex impedance of a portion of (e.g., half of, all of) the cell arrangement can be used to obtain information about the SoC and SoH of a portion of the cell arrangement. The cell arrangement can include one or more electrochemical cells. An electrochemical cell can include a galvanic cell (e.g., voltaic cell), which can convert chemical energy to electrical energy, or an electrolytic cell (e.g., electrolysis cell), which can use electrical energy to drive a chemical reaction. Examples of galvanic cells can include batteries and or fuel cells. Examples of electrolytic cells can include a water electrolysis cell, which can produce hydrogen using electrical power.

Making an EIS measurement can include measuring a current through the cell arrangement, a voltage across the cell arrangement, or both. A measured current and voltage can be used to determine the complex impedance of the cell arrangement. Measuring a current can include measuring a voltage across a resistance (e.g., a shunt resistance), such as can be in series with the cell arrangement. The complex impedance of the cell arrangement at a specified EIS frequency can be used to determine or infer one or more EIS parameters (e.g., EIS properties).

Systems and methods for determining a cell and/or battery temperature using EIS are discussed in Tanovic et al., U.S. patent application Ser. No. 17/715,686 entitled “TECHNIQUE FOR ESTIMATION OF INTERNAL BATTERY TEMPERATURE,” filed on Apr. 7, 2022 (Attorney Docket No. 3867.C18US1), and Yaul et al., U.S. Provisional Patent Application Ser. No. 63/174,646 entitled “TECHNIQUE FOR ESTIMATION OF INTERNAL BATTERY TEMPERATURE,” filed on Apr. 14, 2021 (Attorney Docket No. 3867.A46PRV), which are hereby incorporated by reference herein in their entirety.

The present inventors have recognized, among other things, that it can be beneficial to monitor the temperature value of one or more electrochemical cells in a cell arrangement. Monitoring the temperature values of one or more cells can help to one or more of determine whether the cell arrangement is operating properly, determine if the cell arrangement is safe to continue operating, or determine if the cell arrangement is aging as expected. In an approach, one or more thermistors can be used to monitor electrochemical cells in a cell arrangement. For example, three thermistors can be distributed throughout a cell arrangement with ten cells. However, the thermistors may measure a temperature value on the surface of one or more of the electrochemical cells, such as can differ from a temperature inside the electrochemical cells. Additionally, it can be one or more of expensive or difficult to monitor each of the electrochemical cells.

The present inventors have recognized, among other things, that using EIS to determine a temperature of one or more electrochemical cells in a cell arrangement can allow for the determination of a temperature inside the electrochemical cells (e.g., a core temperature), a determination of the temperature of more electrochemical cells than may be monitored with thermistors (e.g., all electrochemical cells), or both. The determined temperature values can be compared to reference temperature values, and a result of the comparison can be used to make one or more determinations about the cell arrangement, such as if the cell arrangement is aging as expected.

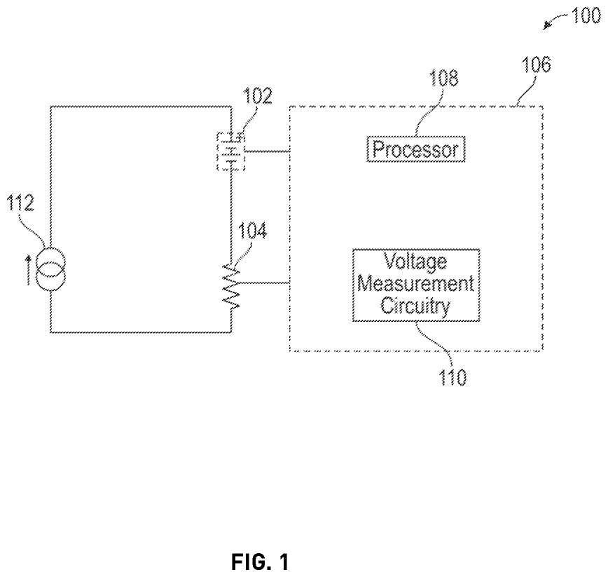

FIG. 1 shows an example of an electrochemical impedance spectroscopy (EIS) monitoring system 100. The EIS monitoring system 100 can be configured for determining a parameter value corresponding to a cell arrangement including two or more electrochemical cells. FIG. 1 shows that the EIS monitoring system 100 can include a cell arrangement 102, a sense resistor 104, an EIS measurement system 106, and a test current source or sink 112. The EIS monitoring system 100 can be configured to determine one or more EIS parameters (e.g., conduct EIS measurements), analyze one or more determined EIS parameters, or both. To determine an EIS parameter of the cell arrangement 102, the EIS monitoring system 100 can measure a voltage across one or more electrochemical cells of the cell arrangement 102 at a specified EIS frequency. The EIS monitoring system 100 can measure a current through corresponding ones of the one or more electrochemical cells at the specified EIS frequency, The EIS monitoring system 100 can determine the impedance of the one or more cells at the specified EIS frequency (e.g., using the voltage and current values), and use this determined impedance to determine an EIS parameter. The EIS monitoring system 100 can optionally use multiple determined impedance values (e.g., multiple impedance values at the same frequency but different times, impedance values at different frequencies) to determine an EIS parameter. In an example, the EIS monitoring system 100 can determine or estimate a temperature corresponding to one or more of the cells in the cell arrangement 102, such as can include determining or estimating the temperature at least in part using an EIS measurement.

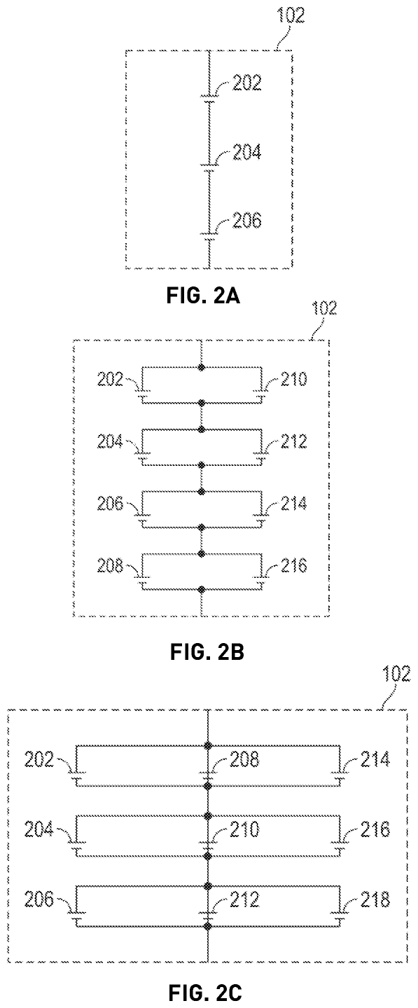

The cell arrangement 102 can include at least one of a battery cell (e.g., a lead acid battery cell, a lithium-ion battery cell), a fuel cell (e.g., a hydrogen fuel cell), an electrolysis cell (e.g., a water electrolysis cell, such as a proton exchange membrane (PEM) electrolysis cell or solid oxide electrolysis cell, a chloralkali electrolysis cell, a molten salt electrolysis cell), or other electrochemical cell. The cell arrangement can include one or more electrochemical cells, such as can include one electrochemical cell, two electrochemical cells, three electrochemical cells, four or more electrochemical cells, 10 or more electrochemical cells, or 100 or more electrochemical cells. All of the electrochemical cells can be of the same type (e.g., same chemistry, same nominal voltage, same capacity), or one or more of the cells can be of a different type than one or more of the other cells. The one or more cells can include a series arrangement of electrochemical cells, a parallel arrangement of electrochemical cells, or both. The cell arrangement is discussed in more detail with respect to FIG. 2A through FIG. 2C below.

The sense resistor 104 can be placed in series with the cell arrangement 102, which can result in a current through the sense resistor 104 matching a current through the cell arrangement 102. In an example, the sense resistor 104 can include a parallel arrangement of a plurality of sense resistors. The sense resistor 104 can have any resistance value. The sense resistor 104 can be a four-wire resistor. For example, a first terminal of the sense resistor 104 can have two leads, and a second terminal of the sense resistor 104 can have two leads. One of the leads at each terminal can be used for current conduction (e.g., a conduction lead, in series with the cell arrangement 102) and one of the leads at each terminal can be used for voltage measurement (e.g., a measurement lead, connected to the voltage measurement circuitry 110). A four-wire resistor can remove, reduce, or otherwise tailor the effect of a resistor lead (e.g., a conductor, such as a metallic conductor, coupled to a resistive material, such as a carbon material or a copper material), on a voltage measurement, such as by reducing a current through the measurement lead to a high input impedance voltage measurement circuit. In an example, the leads can be one or more of noisier or more inductive than the resistive material, such as can make it desirable to remove or reduce an effect of the leads.

FIG. 1 shows that the EIS measurement system 106 can be coupled to the cell arrangement 102, the sense resistor 104, or both. The EIS measurement system 106 can include a processor 108, and voltage measurement circuitry 110. The EIS measurement system 106 can optionally include one or more other circuits, such as a multiplexer or a communication circuit. The EIS measurement system 106 can be configured for measuring one or more EIS parameters of the cell arrangement 102.

The voltage measurement circuitry 110 can be configured to measure respective voltages across the sense resistor 104, one or more cells or parallel cell groups in the cell arrangement 102, or both. The voltage measurement circuitry 110 can include a multiplexer and a voltage measurement device. The multiplexer can be coupled to respective individual ones of the sense resistor 104 or parallel cell groups. The multiplexer can be configured to couple a selected individual one of the voltages to the voltage measurement device. In an example, the voltage measurement circuitry 110 can be configured to measure a voltage across one or more cells in the cell arrangement 102, such as can include a voltage across the cell arrangement 102.

The voltage measurement device can be any circuit capable of measuring a voltage (e.g., producing a signal indicative of a voltage), such as a voltmeter. The voltage measurement device can be configured to measure a direct current (DC) voltage, an alternating current (AC) voltage, or both. The voltage measurement device can be configured to measure an AC voltage across a range of frequencies, such as can match or at least partially overlap with a range of frequencies used for EIS measurements. The voltage measurement circuitry 110 can be configured to measure a voltage across individual ones of the at least two of the two or more electrochemical cells at the specified EIS frequency.

The processor 108 (e.g., the assessment circuit) can be coupled to the voltage measurement circuitry. The processor 108 can be configured to calculate at least one of an AC or DC current through the cell arrangement. The processor 108 can be coupled to the voltage measurement circuitry 110, such as can include being coupled to one or more of the multiplexer or the voltage measurement device. For example, the processor 108 can be configured to control the multiplexer to determine which sense resistor or cell group is coupled to the voltage measurement device.

An input impedance of the voltage measurement circuitry 110, such as can include an input impedance of one or more of the multiplexer or the voltage measurement device, can be configured to have a specified value. The input impedance of the voltage measurement circuitry 110 can be configured to be large (e.g., greater than 100 kiloohms, greater than 1 megaohm, greater than 10 megaohms), such as to reduce a current through the measurement leads of the sense resistors. An increased input impedance of the voltage measurement circuitry 110 can help to reduce or otherwise tailor an effect the voltage measurement circuitry 110 has on the voltage across one or more sense resistors, increase or otherwise tailor an accuracy or specificity of a voltage measured by the voltage measurement circuitry 110, or both. In an example, the input impedance of the voltage measurement circuitry 110 can be configured to be large as compared to the impedance of one or more of the sense resistors, such as can include 100 times larger, 1,000 times larger, or 10,000 times larger.

The processor 108 can be configured to calculate the current through the cell arrangement 102 by calculating the current through the sense resistor 104. The processor 108 can determine the current through a sense resistor by dividing the voltage across the sense resistor by the resistance value of the sense resistor. The resistance value can be a specified, determined, or calibrated value. For example, the processor 108 can have a calibrated resistance value for the sense resistor 104 stored in memory, and can use these values when determining a current through the corresponding sense resistor.

The test current source or sink 112 can provide a test current through the cell arrangement 102, such as to make one or more EIS measurements (e.g., forcing the cell arrangement 102 with a specific frequency or range of frequencies and measuring the response, such as to determine an EIS parameter). The test current source or sink 112 can be configured to provide a test current to the cell arrangement 102 and to the sense resistor 104. The test current source or sink 112 can be coupled to the processor 108. The processor 108 can cause the test current source or sink 112 to generate a test current. The processor 108 can then determine a current through the cell arrangement 102, such as by determining a current through the parallel arrangement of a plurality of sense resistors 104, as discussed above. The current through the cell arrangement 102 can be used, such as used in conjunction with a voltage across the cell arrangement 102, to determine an EIS parameter of the cell arrangement 102. In an example, the test current source or sink 112 can be omitted. For example, the test current source or sink 112 can be provided by another system, a system using the cell arrangement 102 can provide the test current source or sink 112 (e.g., charging currents can be used to force the battery, discharging currents can be used to force the battery).

The test current source or sink 112 can provide a configurable test current, such as can be configured by a user, the processor 108, or both. The test current source or sink 112 can provide an AC test current, a DC test current, or both. The test current source or sink 112 can provide a test current of a specified magnitude. The test current source or sink 112 can provide an AC test current of a specified waveform. For example, the test current source or sink 112 can provide an AC test current that is one or more of a sine wave, a square wave, a triangle wave, a sawtooth wave, or any other waveform. In an example, a square wave can be used, such as to force the cell arrangement 102 across a range of frequencies (e.g., the frequency composition of the square wave).

In an example, the cell arrangement 102 can be immersively cooled, such as in a liquid coolant. The cell arrangement 102 can be configured to allow the liquid coolant to flow between at least two of the electrochemical cells in the cell arrangement. For example, the cell arrangement 102 can be submerged in a tank containing a coolant (e.g., antifreeze), and there can be a gap between two or more electrochemical cells to allow the liquid coolant to flow through the cell arrangement 102. The coolant can be actively cooled, such as by passing the coolant through a radiator. In this example, a surface temperature of one or more of the electrochemical cells can generally match the coolant temperature value, such as can make a surface temperate measurement an inaccurate indication of the internal temperature of the electrochemical cell. In an example, a liquid coolant can be used to cool a battery back, but the cell arrangement 102 may not be immersed in the liquid. For example, liquid coolant can flow through piping that surrounds the cell arrangement 102, such as to exchange heat with the cell arrangement 102. Then, the liquid coolant can flow through a radiator, such as to exchange heat with the environment. However, the liquid coolant might not directly contact the cell arrangement 102, such as can result in the surface temperature of the cell arrangement 102 not matching a temperature of the liquid coolant.

FIG. 2A is a schematic drawing of an example of portions of a cell arrangement 102. FIG. 2A shows that the cell arrangement 102 can include a first electrochemical cell 202, a second electrochemical cell 204, and a third electrochemical cell 206. The first electrochemical cell 202, the second electrochemical cell 204, and the third electrochemical cell 206 can be arranged in series. This can result in the currents through the first electrochemical cell 202, the second electrochemical cell 204, and the third electrochemical cell 206 matching (e.g., all of the cells in the series arrangement have the same current value). FIG. 2A can show a configuration referred to as 3S1P (e.g., 3 series arrangements of 1 cell in parallel (e.g., a single cell)). The voltage measurement circuitry can be configured to measure a respective voltages across and/or determine respective impedances of each of the first electrochemical cell 202, the second electrochemical cell 204, and the third electrochemical cell 206.

FIG. 2B is a schematic drawing of an example of portions of a cell arrangement 102. FIG. 2B shows that the cell arrangement 102 can include a first electrochemical cell 202, a second electrochemical cell 204, a third electrochemical cell 206, a fourth electrochemical cell 208, a fifth electrochemical cell 210, a sixth electrochemical cell 212, a seventh electrochemical cell 214, and an eighth electrochemical cell 216. The first electrochemical cell 202 can be arranged in parallel with the fifth electrochemical cell 210 to form a first parallel arrangement (e.g., cell group). The second electrochemical cell 204 can be arranged in parallel with the sixth electrochemical cell 212 to form a second parallel arrangement. The third electrochemical cell 206 can be arranged in parallel with the seventh electrochemical cell 214 to form a third parallel arrangement. The fourth electrochemical cell 208 can be arranged in parallel with the eighth electrochemical cell 216 to form a fourth parallel arrangement. The first parallel arrangement, the second parallel arrangement, the third parallel arrangement, and the fourth parallel arrangement can be arranged in series to form the cell arrangement 102. This can result in the currents through the first parallel arrangement, the second parallel arrangement, the third parallel arrangement, and the fourth parallel arrangement matching. FIG. 2B can show a configuration referred to as 4S2P (e.g., 4 series arrangements of 2 cells in parallel). The voltage measurement circuitry can be configured to measure a respective voltages across and/or determine respective impedances of each of the first parallel arrangement, the second parallel arrangement, the third parallel arrangement, and the fourth parallel arrangement.

FIG. 2C is a schematic drawing of an example of portions of a cell arrangement 102. FIG. 2B shows that the cell arrangement 102 can include a first electrochemical cell 202, a second electrochemical cell 204, a third electrochemical cell 206, a fourth electrochemical cell 208, a fifth electrochemical cell 210, a sixth electrochemical cell 212, a seventh electrochemical cell 214, an eighth electrochemical cell 216, and a ninth electrochemical cell 218. The first electrochemical cell 202, the fourth electrochemical cell 208, and the seventh electrochemical cell 214 can be arranged in parallel to form a first parallel arrangement. The second electrochemical cell 204, the fifth electrochemical cell 210, and the eighth electrochemical cell 216 can be arranged in parallel to form a second parallel arrangement. The third electrochemical cell 206, the sixth electrochemical cell 212, and the ninth electrochemical cell 218 can be arranged in parallel to form a third parallel arrangement. The first parallel arrangement, the second parallel arrangement, and the third parallel arrangement can be arranged in series to form the cell arrangement 102. This can result in the currents through the first parallel arrangement, the second parallel arrangement, and the third parallel arrangement matching. FIG. 2C can show a configuration referred to as 3S3P (e.g., 3 series arrangements of 3 cells in parallel). The voltage measurement circuitry can be configured to measure respective voltages across and/or determine respective impedances of each of the first parallel arrangement, the second parallel arrangement, and the third parallel arrangement.

The EIS monitoring system 100 (e.g., using the EIS measurement system 106) can be configured to take an EIS measurement corresponding to one or more of (e.g., every) cell in the cell arrangement 102, such as can include determining or estimating the temperature value of every cell in the cell arrangement 102. In an example, the EIS monitoring system 100 can be configured to determine or estimate a temperature value corresponding to one or more of (e.g., every) parallel arrangement of 2 or more cells (e.g., first through fourth parallel arrangements in FIG. 2B, the first through third parallel arrangements in FIG. 2C). In an example, the EIS monitoring system 100 may not be configured to determine an EIS parameter corresponding to each individual cell in a given parallel arrangement (e.g., each of the first electrochemical cell 202 and the fifth electrochemical cell 210 in FIG. 2A). In an example, the EIS monitoring system 100 may not measure the current through each individual cell in a given parallel arrangement, but may rather measure the total current through the parallel arrangement (e.g., by measuring the current through the sense resistor 104). In this example, the EIS monitoring system 100 can determine a combined or average EIS parameter of the cells in a parallel arrangement. For example, the EIS monitoring system 100 can determine a composite, average, or otherwise joint value of the first electrochemical cell 202 and the fifth electrochemical cell 210 in FIG. 2A (e.g., if the first electrochemical cell 202 is hotter than the fifth electrochemical cell 210, the determined temperature value of the first parallel arrangement can be an average or intermediate value of the temperature values of the first electrochemical cell 202 and the fifth electrochemical cell 210.)

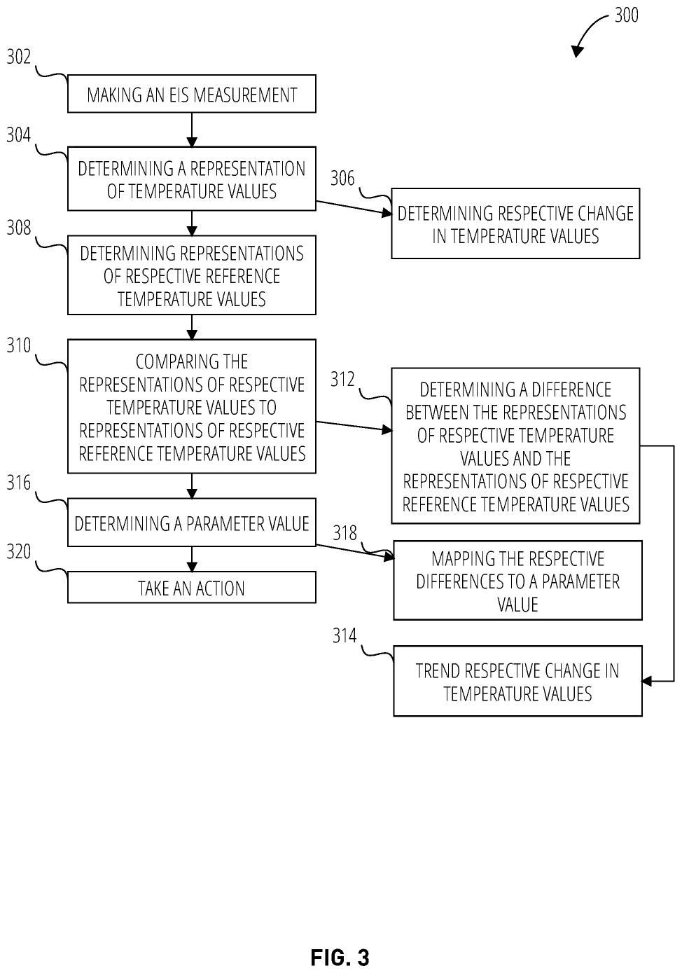

FIG. 3 shows an example of portions of a method 300 for operating an EIS monitoring system 100. The method 300 can include a method for determining a parameter value corresponding to a cell arrangement including two or more electrochemical cells. At step 302, an EIS measurement can be made. This can include making an EIS measurement of respective individual ones of at least two of the two or more electrochemical cells. The EIS measurement can include determining an impedance value (e.g., a complex impedance, including resistive components and reactive components) of respective individual ones of the electrochemical cells at a specified EIS frequency. For example, an EIS measurement can be made for at least two of the cells in the cell arrangement 102 of FIG. 2A (e.g., at least two of the first electrochemical cell 202, the second electrochemical cell 204, and the third electrochemical cell 206). The EIS measurement can be made with an EIS measurement system (e.g., the EIS measurement system 106). The EIS measurement system 106 can be configured to determine a complex impedance value corresponding to the individual ones of the at least two of the two or more electrochemical cells at a specified EIS frequency, such as discussed above. The EIS measurement system can be configured to determine the complex impedance value corresponding to the individual ones of the at least two of the two or more electrochemical cells using a measured voltage across, and a determined current through, the respective individual ones of the at least two of the two or more electrochemical cells.

In an example where the cell arrangement 102 includes parallel arrangements of electrochemical cells (e.g., as shown in FIG. 2B and FIG. 2C), making an EIS measurement of respective individual ones of at least two of the two or more electrochemical cells can include making an EIS measurement of respective individual ones of at least two of the two or more parallel arrangements of electrochemical cells. For example, the parallel arrangements can be treated as individual electrochemical cell (e.g., the first electrochemical cell 202 and the fifth electrochemical cell 210 in FIG. 2B forming the first parallel arrangement can be treated as a single electrochemical cell). In this example electrochemical cell can refer to two or more electrochemical cells arranged in parallel. In an example, an EIS measurement can be made on a group including a series arrangement of cells, alternatively or in addition to a parallel arrangement.

In an example, step 302 can be performed multiple times, such as can include performing step 302 multiple times before step 304 is performed. For example, an EIS measurement for two or more cells or cell groups can be performed. Step 302 can be performed multiple times at different EIS frequencies, such as for two or more cells or cell groups.

At step 304, a representation of one or more temperature values can be determined. This can include determining a representation of respective temperature values corresponding to the at least two (e.g., all of, all but one, all but two) of the two or more electrochemical cells, such as using the respective EIS measurements. For example, a representation of respective temperature values of the first electrochemical cell 202, the second electrochemical cell 204, and the third electrochemical cell 206 of FIG. 2A can be determined. The representations of respective temperature values can include a representation (e.g., a unitless number, a temperature in specified units (e.g., Fahrenheit, Celsius), a value that is indicative of a temperature) that can be determined using one or more of the results of EIS measurements performed in step 302. For example, the EIS measurement system 106 (e.g., using the processor 108) can be configured to determine a representation of respective temperature values corresponding to at least two of the two or more electrochemical cells using the EIS measurement of corresponding ones of the at least two electrochemical cells.

At step 306, determining the representation of respective temperature values can include determining a respective change in temperature values of respective individual ones of the electrochemical cells, such as corresponding to a change in temperature of the respective electrochemical cells due to charging of the cell arrangement at a specified rate for a specified length of time. For example, an initial temperature value for one or more electrochemical cells can be determined, such as at step 302 and step 304. Following the initial measurement, the cell arrangement can be subjected to a current, such as a charging or discharging current, for a length of time. Following this, another temperature value can be determined for the one or more electrochemical cells. The respective differences in the corresponding temperature values (e.g., temperature values corresponding to the same electrochemical cell) can be determined, and can be used as respective change in temperature values. In an example, the determined respective change in temperature values can be due at least in part to a resistance of the electrochemical cells (e.g., a resistance of the electrochemical cells causes the cells to produce heat as current passes through them).

In an example, the current can have a specified value, the length of time can have a specified duration, or both. In this example, it can be desirable to use a current that is configurable or otherwise controllable, such as can include a charging current. For example, a charging current can be configured to have a specified value for a specified duration. In an example, a discharging current (e.g., a current due to a use of the cell arrangement) can be more difficult to control than a charging current, such as can be due to the discharging current being dependent on the use of the cell system using the cell arrangement.

At step 308, representations of respective reference temperature values can be determined. This can include determining representations of respective reference temperature values based on expected temperature values of a reference cell arrangement configured similarly to the cell arrangement and under similar conditions as the cell arrangement. The reference cell arrangement can be one or more of a digital model of the cell arrangement or the cell arrangement before the cell arrangement has degraded due to use (e.g., when the cell arrangement was new). The reference cell arrangement can be configured to match one or more of the properties of the cell arrangement, which can include one or more of cell composition, cell number, cell configuration (e.g., 3S2P), cell thermal properties, or installation properties (e.g., location of installation in an electric vehicle, such as including heat sources (e.g., motors), heat sinks (e.g., body panels, coolant)).

In an example where the reference cell arrangement is the cell arrangement, one or more measurements can be conducted while the cell arrangement is new (e.g., at the factory), and the result of these measurements can be stored as the representation of respective temperature values. In this example, the representation of respective temperature values can be determined using the EIS measurement system (e.g., after an electric vehicle is assembled, the EIS monitoring system 100 performs operations to determine the representation of respective reference temperature values using the EIS measurement system 106). The representations of respective temperature values can be determined using the identical cell arrangement (e.g., measurements corresponding to a specific electric vehicle), or can be determined using an analogous cell arrangement (e.g., measurements are conducted using a specific model of electric vehicle, and these measurements are used across a number of electric vehicles of the same model).

In an example where the reference cell arrangement is a digital model, the digital model can be configured to model one or more of the chemical, electrical, or thermal properties of the cell arrangement. For example, the digital model can model the heat that is generated in the cell arrangement due to a specified current flow, which can include modeling the locations at which the heat is generated. The digital model can model how the heat flows (e.g., from hot regions to cold regions). The representations of respective reference temperature values can be determined by running a simulation of the digital model. The digital model can be configured to include at least one thermal property of the cell arrangement and at least one thermal property of an environment in which the cell arrangement is installed. For example, an ambient environmental temperature sensor can be used to sense an environmental temperature, and the digital model can be selected or customized to provide an accurate digital model that can represent the sensed environmental temperature. The digital model can be configured to model at least one of a new cell arrangement, a healthy cell arrangement, or a cell arrangement following a specified aging trajectory (e.g., the model is configured to take into account the past use of the cell arrangement (e.g., how many times the cell arrangement has been discharged, how aggressively the cell arrangement has been used) and factor this into the reference temperature values). In an example, the digital model can be updated recurrently, such as during charging of the cell arrangement, discharging of the cell arrangement, or in all conditions.

The representations of respective reference temperature values can include reference change in temperature values. The reference change in temperature values can be determined similarly to the respective change in temperature values determined in step 306. For example, the digital model can be simulated to charge at the same specified rate, the same specified duration, or both, as the cell arrangement.

At step 310, the representations of respective temperature values can be compared to representations of respective reference temperature values. For example, a temperature value of one or more of the cells or cell groups in the cell arrangement 102 can be compared to a temperature value of corresponding cells or cell groups in the reference cell arrangement. If the temperature values deviate by more than a specified threshold, an action can be taken, such as at step 320. Comparing the temperature values of the cell arrangement to temperature values of a reference cell arrangement can be desirable, such as compared to just monitoring for a high temperature threshold of the cells in the cell arrangement. For example, the methods of the present disclosure can help allow for the aging of the cell arrangement to be monitored or tracked. This can help to schedule maintenance, adjust lifetime expectations, or adjust or otherwise tailor parameters of a system using the cell arrangement, such as to extend a usable life of the cell arrangement. Monitoring the internal (e.g., core) temperatures of two or more cells or cell groups in the cell arrangement can allow for the generation of a pack level thermal model of the behavior of the cell arrangement.

Additionally, monitoring each cell or cell group can be desirable because the properties of one or more cells or cell groups can disperse over time, use, or both. For example, the impedance of an electrochemical cell can be described by a statistical equation. A new cell can have an impedance within a specified range (e.g., within a specified statistical distribution). As the cell is used, the impedance of the cell can increase, such as due to aging. The impedance of the cell can continue to be described by a statistical equation, but the width or spread of the statistical distribution (e.g., the standard deviation) can increase. For example, cells that have been charged and discharged 150 times can have a larger average difference in impedance than new cells. This can make monitoring a cell arrangement challenging. For example, if thermistors are used to monitor the surface temperature of some cells in a cell arrangement, inferences may be needed about core temperatures and temperatures of cells that are not contacting a thermistor. These inferences can increase in uncertainty as the cell arrangement ages. Using the method 400, a dispersion in properties of one or more cells can be tracked, such as can allow for the reconfiguration of a system using the cell arrangement.

At step 312, comparing the representations of respective temperature values to representations of respective reference temperature values can include determining respective differences between the representation of respective temperature values and the representations of respective reference temperature values. Step 312 can include comparing the change in temperature values to reference change in temperature values. For example, the change in temperature of electrochemical cells within the cell arrangement after charging at a rate of 10 amperes for 15 minutes can be compared to reference change in temperature values of a digital model of the electrochemical cell after charging at a rate of 10 amperes for 15 minutes. In an example, the reference change in temperature values can be stored values of the change in temperature of electrochemical cells in the cell arrangement after charging at a rate of 10 amperes for 15 minutes when the cell arrangement was new.

At step 314, respective change in temperature values can be trended. This can include trending the change in temperature values of respective individual ones of the electrochemical cells across at least two charging events. For example, the change in temperature values of electrochemical cells after charging at a rate of 10 amperes for 15 minutes can be trended between charging events. The trend can indicate how quickly and to what degree the electrochemical cells are changing (e.g., aging). The trend can be compared to a reference trend. The reference trend can be based on an expected degradation of an electrochemical cell. If one or more of the electrochemical cells deviate from the expected aging trajectory, such as by a specified threshold amount, an action can be taken, such as at step 320.

At step 316, a parameter value can be determined. This can include determining a parameter value corresponding to at least one of the cell arrangement or one or more of the respective ones of the at least two electrochemical cells using a result of the comparison. For example, a parameter value can be determined corresponding to one or more (e.g., each) of the electrochemical cells, the cell arrangement (e.g., the cell arrangement as a whole), or both. The parameter value can include one or more of a state-of-health value, a state-of-safety value, a thermal health indicator (e.g., how the battery performs thermally, such as a ratio between a maximum temperature the electrochemical cell will reach under specified use conditions and a specified maximum cell temperature), a resistance value, or another parameter value (e.g., a value indicative of a remaining life of the electrochemical cell).

At step 318, determining a parameter value can include mapping respective differences (e.g., the respective differences determined in step 312) to a parameter value for respective individual ones of the at least two of the two or more electrochemical cells. For example, if the difference is small for an electrochemical cell, a low (e.g., good) parameter value can be mapped. If the difference is large, a high (e.g., bad) parameter value can be mapped. In an example, when one of the parameter values exceeds a specified threshold (e.g., a threshold indicative of a safety level, a threshold indicative of normal operation), an action can be taken, such as at step 320.

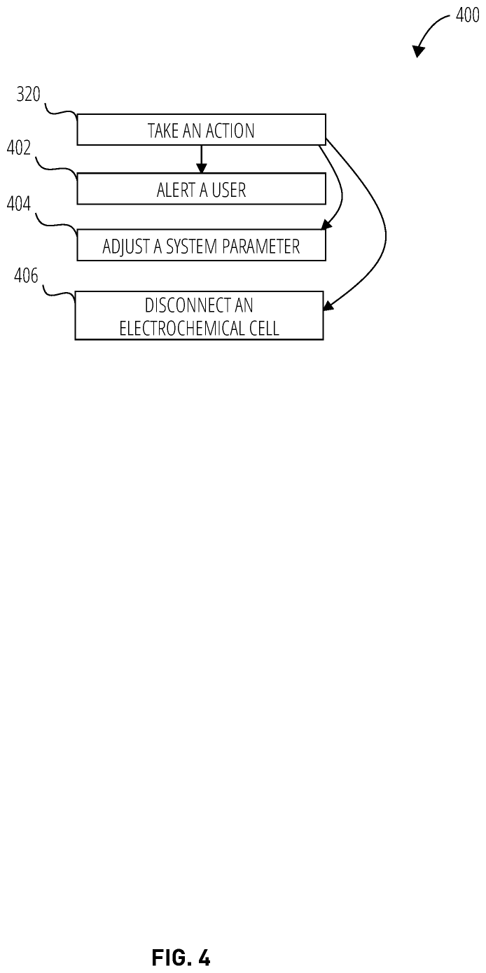

At step 320, an action can be taken, such as in response to the parameter value determined in step 316. Various actions are discussed in more detail below with respect to FIG. 4.

The shown order of steps is not intended to be a limitation on the order in which the steps are performed. In an example, two or more steps may be performed simultaneously or at least partially concurrently.

FIG. 4 shows an example of portions of a method 400 for operating an EIS monitoring system, such as the EIS monitoring system 100. The method 400 can be performed alternatively or in addition to the method 300. For example, the method 400 can be performed following step 320 of the method 300. At step 402, a user can be alerted. For example, a user could be informed of the result of one or more determinations of the assessment circuit, such as the parameter value. In an example, a user can be alerted when the cell arrangement 102 is determined to be in a healthy or safe state. For example, the user could be alerted after an initialization process (e.g., after an electric vehicle is powered on). In an example, a user can be alerted only when the cell arrangement 102 is determined to be in an other than healthy or safe state, such as a state in which maintenance is needed (e.g., an electric vehicle needs maintenance, such as within a specified length of time or within a specified distance driven), a state in which the cell arrangement 102 cannot be safely used (e.g., an electric vehicle will not operate because of a determined state of the cell arrangement 102), or both.

At step 404, a system parameter can be adjusted. For example, a parameter of a system that is using the cell arrangement 102 can be adjusted, such as can include being adjusted by the processor 108. For example, a limit on at least one of a charging rate or a discharging rate of the cell arrangement 102 can be configured or re-configured. This can include reducing or otherwise derating a maximum charging rate, discharging rate, or both. For example, it can be determined that the cell arrangement 102 is safe to use, but that limits must be placed on a charging rate to ensure safety (e.g., ensure the cell arrangement 102 or a portion of the cell arrangement 102 does not exceed a specified operating temperature, or does not exceed a specified temperature configured to provide or increase a life span of the cell arrangement 102). In an example, the limit can be set based on the parameter value of a least healthy cell. The least healthy cell can include a cell that is indicated to have one or more of the largest resistance, the largest reduction in health or capacity, the lowest SoH, the lowest SoS, or a cell that is determined to be the most likely to overheat, such as due to a configuration of the cell arrangement 102, a configuration of the installation of the cell arrangement 102 (e.g., the cooling configuration, proximity to other heat sources), or both.

At step 406, an electrochemical cell can be disconnected. For example, the cell arrangement 102 can be configured such that one or more cells can be disconnected (e.g., bypassed), such as to allow the cell arrangement 102 to continue operating. For example, if the first electrochemical cell 202 in FIG. 2A is determined to be “bad” (e.g., no longer safe to operate, no longer operating at the level required to form a part of the cell arrangement 102), the first electrochemical cell 202 can be disconnected and the operable portion of the cell arrangement 102 can include the second electrochemical cell 204 and the third electrochemical cell 206. In a cell arrangement 102 including parallel arrangements of electrochemical cells, a parallel arrangement can be disconnected.

The shown order of steps is not intended to be a limitation on the order in which the steps are performed. In an example, two or more steps may be performed simultaneously or at least partially concurrently.

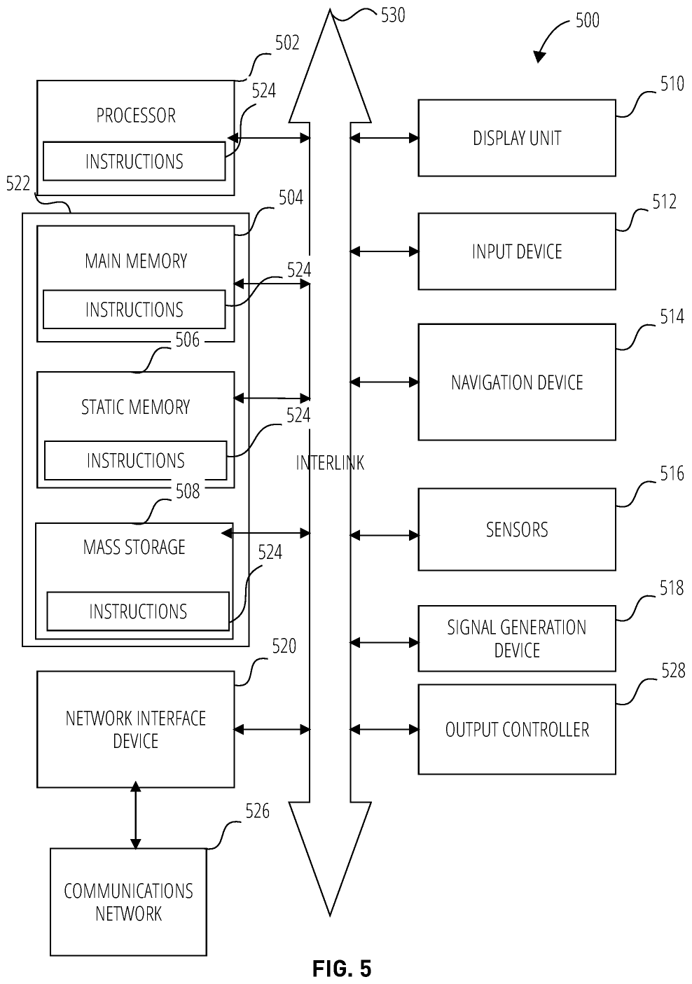

FIG. 5 illustrates a block diagram of an example machine 500 upon which any one or more of the techniques (e.g., methodologies) discussed herein may be implemented. Examples, as described herein, may include, or may operate by, logic or a number of components, or mechanisms in the machine 500. Circuitry (e.g., processing circuitry) is a collection of circuits implemented in tangible entities of the machine 500 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 500 follow.

In alternative examples, the machine 500 may operate as a standalone device or may be connected (e.g., networked) to other machines. In a networked deployment, the machine 500 may operate in the capacity of a server machine, a client machine, or both in server-client network environments. In an example, the machine 500 may act as a peer machine in peer-to-peer (P2P) (or other distributed) network environment. The machine 500 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 500 may include a hardware processor 502 (e.g., a central processing unit (CPU), a graphics processing unit (GPU), a hardware processor core, or any combination thereof), a main memory 504, a static memory (e.g., memory or storage for firmware, microcode, a basic-input-output (BIOS), and mass storage 508 (e.g., hard drives, tape drives, flash storage, or other block devices) some or all of which may communicate with each other via an interlink 530 (e.g., bus). The machine 500 may further include a display unit 510, an alphanumeric input device 512 (e.g., a keyboard), and a user interface (UI) navigation device 514 (e.g., a mouse). In an example, the display unit 510, input device 512 and UI navigation device 514 may be a touch screen display. The machine 500 may additionally include a signal generation device 518 (e.g., a speaker), a network interface device 520, and one or more sensors 516, such as a global positioning system (GPS) sensor, compass, accelerometer, or other sensor. The machine 500 may include an output controller 528, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 502, the main memory 504, the static memory 506, or the mass storage 508 may be, or include, a machine readable medium 522 on which is stored one or more sets of data structures or instructions 524 (e.g., software) embodying or utilized by any one or more of the techniques or functions described herein. The instructions 524 may also reside, completely or at least partially, within any of registers of the processor 502, the main memory 504, the static memory 506, or the mass storage 508 during execution thereof by the machine 500. In an example, one or any combination of the hardware processor 502, the main memory 504, the static memory 506, or the mass storage 508 may constitute the machine readable media 522. While the machine readable medium 522 is illustrated as a single medium, the term “machine readable medium” may include a single medium or multiple media (e.g., a centralized or distributed database, and/or associated caches and servers) configured to store the one or more instructions 524.

The term “machine readable medium” may include any medium that is capable of storing, encoding, or carrying instructions for execution by the machine 500 and that cause the machine 500 to perform any one or more of the techniques of the present disclosure, or that is capable of storing, encoding or carrying data structures used by or associated with such instructions. Non-limiting machine readable medium examples may include solid-state memories, optical media, magnetic media, and signals (e.g., radio frequency signals, other photon based signals, sound signals, etc.). In an example, a non-transitory machine readable medium comprises a machine readable medium with a plurality of particles having invariant (e.g., rest) mass, and thus are compositions of matter. Accordingly, non-transitory machine-readable media are machine readable media that do not include transitory propagating signals. Specific examples of non-transitory machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

In an example, information stored or otherwise provided on the machine readable medium 522 may be representative of the instructions 524, such as instructions 524 themselves or a format from which the instructions 524 may be derived. This format from which the instructions 524 may be derived may include source code, encoded instructions (e.g., in compressed or encrypted form), packaged instructions (e.g., split into multiple packages), or the like. The information representative of the instructions 524 in the machine readable medium 522 may be processed by processing circuitry into the instructions to implement any of the operations discussed herein. For example, deriving the instructions 524 from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 524.

In an example, the derivation of the instructions 524 may include assembly, compilation, or interpretation of the information (e.g., by the processing circuitry) to create the instructions 524 from some intermediate or preprocessed format provided by the machine readable medium 522. The information, when provided in multiple parts, may be combined, unpacked, and modified to create the instructions 524. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 524 may be further transmitted or received over a communications network 526 using a transmission medium via the network interface device 520 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), LoRa/LoRaWAN, or satellite communication networks, mobile telephone networks (e.g., cellular networks such as those complying with 3G, 4G LTE/LTE-A, or 5G standards), Plain Old Telephone (POTS) networks, and wireless data networks (e.g., Institute of Electrical and Electronics Engineers (IEEE) 802.11 family of standards known as Wi-Fi®, IEEE 802.15.4 family of standards, peer-to-peer (P2P) networks, among others. In an example, the network interface device 520 may include one or more physical jacks (e.g., Ethernet, coaxial, or phone jacks) or one or more antennas to connect to the communications network 526. In an example, the network interface device 520 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 500, and includes digital or analog communications signals or other intangible medium to facilitate communication of such software. A transmission medium is a machine-readable medium.

The following, non-limiting examples, detail certain aspects of the present subject matter to solve the challenges and provide the benefits discussed herein, among others.

### EXAMPLES

Example 1 is an electrochemical impedance spectroscopy (EIS) monitoring system for determining a parameter value corresponding to a cell arrangement including two or more electrochemical cells, the EIS monitoring system comprising: an EIS measurement system, configured to determine a representation of respective temperature values corresponding to at least two of the two or more electrochemical cells using an EIS measurement of corresponding ones of the at least two electrochemical cells; an assessment circuit, configured to: compare the representations of respective temperature values to representations of respective reference temperature values, wherein the representations of respective reference temperature values are determined based on expected temperature values of a reference cell arrangement configured similarly to the cell arrangement and under similar conditions as the cell arrangement; and determine a parameter value corresponding to at least one of the cell arrangement or one or more of the respective ones of the at least two electrochemical cells using a result of the comparison.

In Example 2, the subject matter of Example 1 optionally includes wherein the assessment circuit is configured to take an action based on the determined parameter value.

In Example 3, the subject matter of any one or more of Examples 1-2 optionally include wherein: to compare the representations of respective temperature values to representations of respective reference temperature values includes to determine respective differences between the representation of respective temperature values and the representations of respective reference temperature values; and to determine a parameter value includes to map the respective differences to a parameter value for respective individual ones of the at least two of the two or more electrochemical cells.

In Example 4, the subject matter of Example 3 optionally includes wherein a limit on at least one of a charging rate or a discharging rate of the cell arrangement is configured based on the parameter value of a least healthy cell.

In Example 5, the subject matter of any one or more of Examples 1-4 optionally include wherein: the EIS measurement system is configured to determine change in temperature values corresponding to changes in a temperature value of respective individual ones of the electrochemical cells due to charging of the cell arrangement at a specified rate for a specified length of time; and the change in temperature values determined are due at least in part to a resistance of the electrochemical cells.

In Example 6, the subject matter of Example 5 optionally includes wherein the assessment circuit is configured to: trend the change in temperature values of respective individual ones of the electrochemical cells across at least two charging events; and compare the trend to a reference trend based on an expected degradation of an electrochemical cell.

In Example 7, the subject matter of any one or more of Examples 1-6 optionally include wherein: the reference cell arrangement is a digital model of the cell arrangement; the representations of respective reference temperature values are determined by running a simulation of the digital model; and the digital model is configured to include at least one thermal property of the cell arrangement and at least one thermal property of an environment in which the cell arrangement is installed.

In Example 8, the subject matter of Example 7 optionally includes wherein the digital model is configured to model at least one of a new cell arrangement, a healthy cell arrangement, or the cell arrangement following a specified aging trajectory.

In Example 9, the subject matter of any one or more of Examples 1-8 optionally include wherein: the reference cell arrangement is the cell arrangement before the cell arrangement has degraded due to use; and the representations of respective reference temperature values are determined using the EIS measurement system.

In Example 10, the subject matter of any one or more of Examples 1-9 optionally include wherein the EIS measurement system is configured to determine a complex impedance value corresponding to individual ones of the at least two of the two or more electrochemical cells at a specified EIS frequency.

In Example 11, the subject matter of Example 10 optionally includes wherein the EIS measurement system comprises: a test current source or sink, configured to provide a test current to the cell arrangement at the specified EIS frequency; and voltage measurement circuitry, configured to measure a voltage across individual ones of the at least two of the two or more electrochemical cells at the specified EIS frequency.

In Example 12, the subject matter of Example 11 optionally includes wherein the EIS measurement system is configured to determine the complex impedance value corresponding to the individual ones of the at least two of the two or more electrochemical cells using the measured voltage across, and a determined current through, the respective individual ones of the at least two of the two or more electrochemical cells.

In Example 13, the subject matter of any one or more of Examples 1-12 optionally include wherein the cell arrangement is immersively cooled in a liquid coolant, wherein the cell arrangement is configured to allow the liquid coolant to flow between at least two of the electrochemical cells in the cell arrangement.

In Example 14, the subject matter of any one or more of Examples 1-13 optionally include the cell arrangement.

In Example 15, the subject matter of any one or more of Examples 1-14 optionally include wherein the parameter value includes at least one of a state-of-health value, a state-of-safety value, or a thermal health indicator.

Example 16 is a method for determining a parameter value corresponding to a cell arrangement including two or more electrochemical cells, the method comprising: making an EIS measurement of respective individual ones of at least two of the two or more electrochemical cells; determining a representation of respective temperature values corresponding to the at least two of the two or more electrochemical cells using the respective EIS measurements; determining representations of respective reference temperature values based on expected temperature values of a reference cell arrangement configured similarly to the cell arrangement and under similar conditions as the cell arrangement; comparing the representations of respective temperature values to representations of respective reference temperature values; and determining a parameter value corresponding to at least one of the cell arrangement or one or more of the respective ones of the at least two electrochemical cells using a result of the comparison.

In Example 17, the subject matter of Example 16 optionally includes wherein: comparing the representations of respective temperature values to representations of respective reference temperature values includes determining respective differences between the representation of respective temperature values and the representations of respective reference temperature values; and determining a parameter value includes mapping the respective differences to a parameter value for respective individual ones of the at least two of the two or more electrochemical cells.

In Example 18, the subject matter of any one or more of Examples 16-17 optionally include wherein: determining the representation of respective temperature values includes determining respective change in temperature values of respective individual ones of the electrochemical cells corresponding to a change in temperature of the respective electrochemical cells due to charging of the cell arrangement at a specified rate for a specified length of time; and the determined respective change in temperature values are due at least in part to a resistance of the electrochemical cells.

Example 19 is an electrochemical impedance spectroscopy (EIS) monitoring system for determining a parameter value corresponding to a cell arrangement including two or more electrochemical cells, the EIS monitoring system comprising: an EIS measurement system, configured to determine respective change in temperature values corresponding to at least two of the two or more electrochemical cells using an EIS measurement of corresponding ones of the at least two electrochemical cells, wherein the change in temperature values are due to charging of the cell arrangement at a specified rate for a specified length of time; an assessment circuit, configured to: trend the change in temperature values of respective individual ones of the electrochemical cells across at least two charging events; and compare the trend to a reference trend based on an expected degradation of an electrochemical cell.

In Example 20, the subject matter of Example 19 optionally includes wherein the assessment circuit is configured to take an action based on a result of the comparison.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific examples that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the terms “or” and “and/or” are used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5). Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4).

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like.

Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other examples may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the examples should be determined with reference to the appended claims, along with the full scope of equivalents to which such claims are entitled.

What is claimed is:

1. An electrochemical impedance spectroscopy (EIS) monitoring system for determining a parameter value corresponding to a cell arrangement including two or more electrochemical cells, the EIS monitoring system comprising:
an EIS measurement system, configured to determine a representation of respective temperature values corresponding to at least two of the two or more electrochemical cells using an EIS measurement of corresponding ones of the at least two electrochemical cells;
an assessment circuit, configured to:
compare the representations of respective temperature values to representations of respective reference temperature values, wherein the representations of respective reference temperature values are determined based on expected temperature values of a reference cell arrangement configured similarly to the cell arrangement and under similar conditions as the cell arrangement; and
determine a parameter value corresponding to at least one of the cell arrangement or one or more of the respective ones of the at least two electrochemical cells using a result of the comparison.

2. The EIS monitoring system of claim 1, wherein the assessment circuit is configured to take an action based on the determined parameter value.

3. The EIS monitoring system of claim 1, wherein:
to compare the representations of respective temperature values to representations of respective reference temperature values includes to determine respective differences between the representation of respective temperature values and the representations of respective reference temperature values; and
to determine a parameter value includes to map the respective differences to a parameter value for respective individual ones of the at least two of the two or more electrochemical cells.

4. The EIS monitoring system of claim 3, wherein a limit on at least one of a charging rate or a discharging rate of the cell arrangement is configured based on the parameter value of a least healthy cell.

5. The EIS monitoring system of claim 1, wherein:
the EIS measurement system is configured to determine change in temperature values corresponding to changes in a temperature value of respective individual ones of the electrochemical cells due to charging of the cell arrangement at a specified rate for a specified length of time; and
the change in temperature values determined are due at least in part to a resistance of the electrochemical cells.

6. The EIS monitoring system of claim 5, wherein the assessment circuit is configured to:
trend the change in temperature values of respective individual ones of the electrochemical cells across at least two charging events; and
compare the trend to a reference trend based on an expected degradation of an electrochemical cell.

7. The EIS monitoring system of claim 1, wherein:
the reference cell arrangement is a digital model of the cell arrangement;
the representations of respective reference temperature values are determined by running a simulation of the digital model; and
the digital model is configured to include at least one thermal property of the cell arrangement and at least one thermal property of an environment in which the cell arrangement is installed.

8. The EIS monitoring system of claim 7, wherein the digital model is configured to model at least one of a new cell arrangement, a healthy cell arrangement, or the cell arrangement following a specified aging trajectory.

9. The EIS monitoring system of claim 1, wherein:
the reference cell arrangement is the cell arrangement before the cell arrangement has degraded due to use; and
the representations of respective reference temperature values are determined using the EIS measurement system.

10. The EIS monitoring system of claim 1, wherein the EIS measurement system is configured to determine a complex impedance value corresponding to individual ones of the at least two of the two or more electrochemical cells at a specified EIS frequency.

11. The EIS monitoring system of claim 10, wherein the EIS measurement system comprises:
a test current source or sink, configured to provide a test current to the cell arrangement at the specified EIS frequency; and
voltage measurement circuitry, configured to measure a voltage across individual ones of the at least two of the two or more electrochemical cells at the specified EIS frequency.

12. The EIS monitoring system of claim 11, wherein the EIS measurement system is configured to determine the complex impedance value corresponding to the individual ones of the at least two of the two or more electrochemical cells using the measured voltage across, and a determined current through, the respective individual ones of the at least two of the two or more electrochemical cells.

13. The EIS monitoring system of claim 1, wherein the cell arrangement is immersively cooled in a liquid coolant, wherein the cell arrangement is configured to allow the liquid coolant to flow between at least two of the electrochemical cells in the cell arrangement.

14. The EIS monitoring system of claim 1, further comprising the cell arrangement.

15. The EIS monitoring system of claim 1, wherein the parameter value includes at least one of a state-of-health value, a state-of-safety value, or a thermal health indicator.

16. A method for determining a parameter value corresponding to a cell arrangement including two or more electrochemical cells, the method comprising:
making an EIS measurement of respective individual ones of at least two of the two or more electrochemical cells;
determining a representation of respective temperature values corresponding to the at least two of the two or more electrochemical cells using the respective EIS measurements;
determining representations of respective reference temperature values based on expected temperature values of a reference cell arrangement configured similarly to the cell arrangement and under similar conditions as the cell arrangement;
comparing the representations of respective temperature values to representations of respective reference temperature values; and
determining a parameter value corresponding to at least one of the cell arrangement or one or more of the respective ones of the at least two electrochemical cells using a result of the comparison.

17. The method of claim 16, wherein:
comparing the representations of respective temperature values to representations of respective reference temperature values includes determining respective differences between the representation of respective temperature values and the representations of respective reference temperature values; and
determining a parameter value includes mapping the respective differences to a parameter value for respective individual ones of the at least two of the two or more electrochemical cells.

18. The method of claim 16, wherein:
determining the representation of respective temperature values includes determining respective change in temperature values of respective individual ones of the electrochemical cells corresponding to a change in temperature of the respective electrochemical cells due to charging of the cell arrangement at a specified rate for a specified length of time; and
the determined respective change in temperature values are due at least in part to a resistance of the electrochemical cells.

19. An electrochemical impedance spectroscopy (EIS) monitoring system for determining a parameter value corresponding to a cell arrangement including two or more electrochemical cells, the EIS monitoring system comprising:
an EIS measurement system, configured to determine respective change in temperature values corresponding to at least two of the two or more electrochemical cells using an EIS measurement of corresponding ones of the at least two electrochemical cells, wherein the change in temperature values are due to charging of the cell arrangement at a specified rate for a specified length of time;
an assessment circuit, configured to:
trend the change in temperature values of respective individual ones of the electrochemical cells across at least two charging events; and
compare the trend to a reference trend based on an expected degradation of an electrochemical cell.

20. The EIS monitoring system of claim 19, wherein the assessment circuit is configured to take an action based on a result of the comparison.
